(19) United States
(12) Patent Application Publication
(10) Pub. No.: US 2009/0152615 A1
(43) Pub. Date: Jun. 18, 2009

(54) SEMICONDUCTOR DEVICE AND METHOD FOR MANUFACTURING THE SAME

(76) Inventor: Ji-Ho Hong, Hwaseong-si (KR)

Correspondence Address: SHERR & VAUGHN, PLLC, 620 HERNDON PARKWAY, SUITE 200, HERNDON, VA, 20170, US

(21) Appl. No.: 12/330,588

(22) Filed: Dec. 9, 2008

(30) Foreign Application Priority Data
Dec. 18, 2007 (KR) 10-2007-0133227

(51) Int. Cl. H01L 29/78; H01L 21/3205; H01L 23/48

(52) U.S. Cl. 257/316; 438/586; 257/773; 257/E29.3; 257/E23.168; 257/E21.575

(57) ABSTRACT

Embodiments relate to a semiconductor device that may include a floating gate, an inter poly dielectric formed on and/or over both sides of the floating gate in a bit line direction and on and/or over both side of the floating gate in a word line direction, and a control gate formed on and/or over the IPD. According to embodiments, an IPD may be formed on and/or over a top and four sides of a floating gate. This may increase a coupling ratio of a semiconductor device.

The present application claims priority under 35 U.S.C. 119 to Korean Patent Application No. 10-2007-0133227 (filed on Dec. 18, 2007), which is hereby incorporated by reference in its entirety.

### BACKGROUND

A coupling ratio of a flash device may be an important parameter that may specify characteristics of a flash cell. Although a constant voltage may be applied to a control gate, as a coupling ratio becomes larger, voltage may be applied to a floating gate. This may make a final gate electric field large and more hot electrons may be drawn to the floating gate. Because of this characteristic of a flash cell, it may be important to increase a coupling ratio. In this regard, setting conditions such as a thickness of a floating gate, a thickness and a kind of an inter poly dielectric (IPD), and the like may be important factors.

### SUMMARY

Embodiments relate to a semiconductor device that may simplify a manufacturing process and may improve a coupling ratio, and a method for manufacturing the same.

According to embodiments, a semiconductor device may include at least one of the following: a floating gate, an inter poly dielectric (IPD) formed on and/or over both sides of the floating gate in a bit line direction and on and/or over both sides of the floating gate in a word line direction, and a control gate formed on and/or over the IPD.

According to embodiments, a method for manufacturing a semiconductor device may include at least one of the following: forming a first poly film for forming a floating gate, patterning the floating gate by etching the first poly film in a lattice form of the bit line direction and word line direction, forming an inter poly dielectric (IPD) on and/or over the floating gate, forming a second poly film for forming a control gate on and/or over the IPD and then patterning the control gate by etching the second poly film.

According to embodiments, a method for manufacturing a semiconductor device may include at least one of the following: forming a first poly film for forming a floating gate, forming a photoresist film on and/or over the first poly film, performing a first exposure on and/or over the photoresist film in a first direction, performing a second exposure on and/or over the photoresist on and/or over which the first exposure is performed in a second direction that may be vertical to the first direction, forming a floating gate patterned in a lattice form by performing an etching on and/or over the photoresist film on and/or over which the second exposure is performed and the first poly film, forming an inter poly dielectric (IPD) on and/or over the floating gate, forming a second poly film for forming a control gate on and/or over the IPD and then patterning a control gate by etching the second poly film.

### DRAWINGS

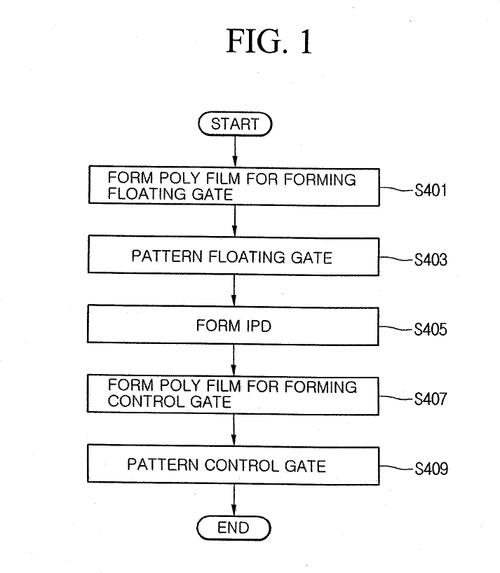

Example FIG. 1 is a flowchart illustrating a method for manufacturing a semiconductor device, according to embodiments.

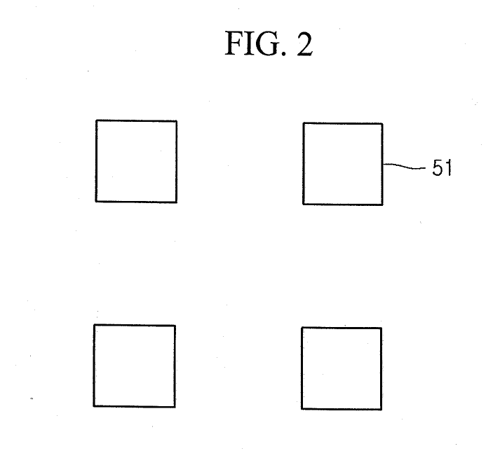

Example FIG. 2 is a drawing illustrating a patterning of a floating gate, according to embodiments.

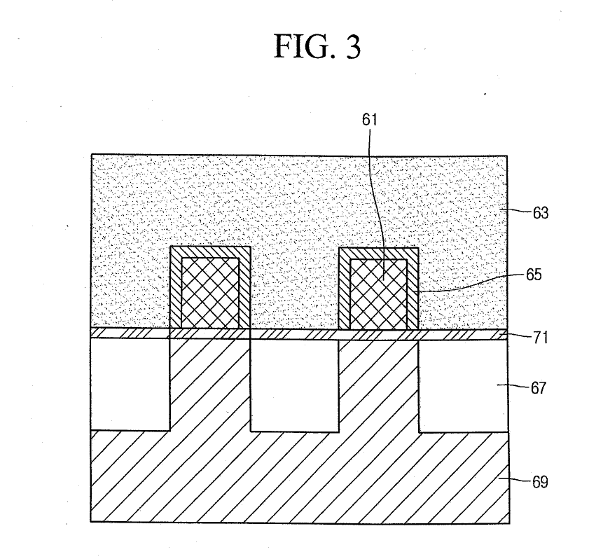

Example FIG. 3 is a cross-sectional view of a semiconductor device in a word line direction, according to embodiments.

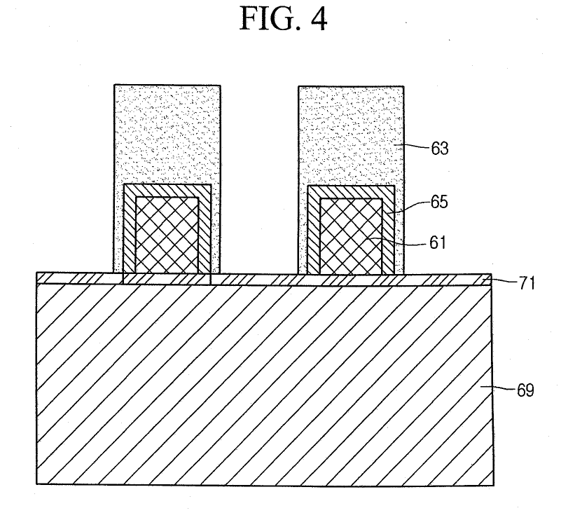

Example FIG. 4 is a cross-sectional view of a semiconductor device in a bit line direction, according to embodiments.

### DESCRIPTION

Example FIG. 1 is a flowchart illustrating a method for manufacturing a semiconductor device, according to embodiments. Referring to example FIG. 1, a first poly film for forming a floating gate may be formed (Step 401). A floating gate may then be patterned, for example by etching the first poly film (Step 403).

Referring to example FIG. 2, when patterning a floating gate by etching a first poly film, the first poly film may be etched and patterned in a lattice form of a bit line direction and a word line direction. Floating gate 51, which may be etched in both a bit line direction and a word line direction, may thereby be formed. According to embodiments, when patterning floating gate 51 by etching the first poly film, floating gate 51, which may be patterned in a lattice form of a bit line direction and a word line direction, may be formed through a one-time exposure process and a one-time etching process.

Referring again to example FIG. 1, according to embodiments, inter poly dielectrics (IPD) on and/or over floating gate 51 may be formed (Step 405). According to embodiments, an IPD may be formed of an oxide-nitride-oxide (ONO) layer. Floating gate 51 may be etched in both a bit line direction and a word line direction. An IPD may thereby be formed on and/or over a top and four side walls of floating gate 51. An IPD may be formed on and/or over both side walls of floating gate 51 in a bit line direction and an IPD may also be formed on and/or over both side walls of floating gate 51 in a word line direction.

A second poly film may be formed, and may form a control gate on and/or over an IPD (Step 407). The second poly film may be formed on and/or over both side walls of the IPD in a bit line direction and on and/or over both side walls of the IPD in a word line direction. A control gate may then be patterned by etching the second poly film (Step 409). A control gate may be formed by etching and patterning the second poly film in a word line direction. A semiconductor device including a floating gate and a control gate may thereby be formed.

When patterning floating gate 51 by etching a first poly film, a first exposure process may be performed on the first poly film in a bit line direction. In addition, a second exposure process may be performed on the first poly film on which the first exposure process may have been performed, in a word line direction. First and second exposure processes may be implemented using the same mask patterned in one direction. Floating gate 51 may be patterned in a lattice form through a one-time etching process, in a state where a first exposure process and a second exposure process may be performed. First and second exposure processes may be performed on a photoresist film that may be formed on and/or over the first poly film. According to embodiments, when patterning floating gate 51 by etching the first poly film, a first exposure process may be performed on the first poly film in a word line direction. A second exposure process may be performed on the first poly film on which the first exposure process may have been performed, in a bit line direction. First and second exposure processes may be implemented using the same masks patterned in one direction. Floating gate 51 may be patterned in a lattice form through a one-time etching process, in a state where a first exposure process and a second exposure process may be performed. First and second exposure processes and may be performed on a photoresist film formed on and/or over the first poly film.

Example FIG. 3 is a cross-sectional view of a semiconductor device in a word line direction, according to embodiments. Example FIG. 4 is a cross-sectional view of a semiconductor device in a bit line direction, according to embodiments. Referring to example FIGS. 3 and 4, a semiconductor device may include floating gate 61, control gate 63, and IPD 65. Floating gate 61 may be formed on and/or over semiconductor layer 69. Oxide film 71 may be formed between semiconductor layer 69 and floating gate 61. Device isolation part 67 may also be formed on and/or over semiconductor layer 69. IPD 65 may be formed of an oxide-nitride-oxide (ONO) layer. IPD 65 may be formed on and/or over both sides of floating gate 61 in a bit line direction and on and/or over both sides of floating gate 61 in a word line direction. Control gate 63 may be formed on and/or over IPD 65. Control gate 63 may be formed on and/or over both sides of IPD 65 in a bit line direction and on and/or over both sides of IPD 65 in a word line direction.

According to embodiments, when forming floating gate 61, a poly film that may be used to form a floating gate in a bit line direction and in a word line direction may be completely etched. Both sides of patterned floating gate 61 in a bit line direction and both sides of patterned floating gate 61 in a word line direction may be exposed. IPD 65 may be formed on and/or over floating gate 61 patterned in a lattice form. Accordingly, IPD 65 may be formed on and/or over a top and four side walls of floating gate 61. This may increase a coupling ratio. According to embodiments, since a poly film that may be etched during a related art control gate etching process may be uniform in any place of a cell area and a peripheral area, control gate 63 may be etched through a one-time patterning process. According to embodiments, an etching process for a cell area and an etching process for a peripheral area may be performed at the same time, which may make it possible to reduce a photolithography process.

According to embodiments, as shown in example FIGS. 3 and 4, IPD 65 may surround floating gate 61 not only in a word line direction but also in a bit line direction. IPD 65 may surround floating gate 61 even in a bit line direction. A capacitance for IPD 65 may therefore be increased. According to embodiments, a coupling ratio of a flash cell may be increased and a quality of a semiconductor device may be improved.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A device comprising:
a floating gate having sides in a bit line direction and sides in a word line direction;
an inter poly dielectric (IPD) formed over both sides of the floating gate in the bit line direction and over both sides of the floating gate in the word line direction; and
a control gate formed over the IPD.

2. The device of claim 1, wherein the IPD comprises an oxide-nitride-oxide (ONO) layer.

3. The device of claim 1, wherein the control gate is formed over both sides of the IPD in the bit line direction and over both sides of the IPD in the word line direction.

4. A method comprising:
forming a first poly film over a semiconductor substrate;
patterning a floating gate by etching the first poly film in a lattice form in a bit line direction and a word line direction;
forming an inter poly dielectric (IPD) over the floating gate;
forming a second poly film over the IPD; and then
patterning a control gate by etching the second poly film.

5. The method of claim 4, wherein etching the first poly film in the lattice form in the bit line direction and the word line direction comprises patterning the first poly film through a one-time exposure process and a one-time etching process.

6. The method of claim 4, wherein patterning the floating gate comprises:
performing a first exposure process on the first poly film in the bit line direction;
performing a second exposure process on the first poly film, to which the first exposure process has been performed, in the word line direction; and then
patterning the floating gate through a single etching process.

7. The method of claim 4, wherein patterning the floating gate comprises:
performing a first exposure process on the first poly film in the word line direction;
performing a second exposure process on the first poly film, to which the first exposure process has been performed, in the bit line direction; and then
patterning the floating gate through a single etching process.

8. The method of claim 4, further comprising forming the IPD over both sides of the floating gate in the bit line direction and over both sides of the floating gate in the word line direction.

9. The method of claim 4, wherein the second poly film is formed over both sides of the IPD in the bit line direction and over both sides of the IPD in the word line direction.

10. The method of claim 9, wherein patterning the control gate comprises etching the second poly film such that the control gate is formed over both sides of the IPD in the bit line direction and over both sides of the IPD in the word line direction.

11. The method of claim 4, wherein patterning the control gate by etching the second poly film comprises etching and pattering the second poly film in the bit line direction.

12. The method of claim 4, wherein patterning the control gate by etching the second poly film comprises etching and pattering the second poly film in the word line direction.

13. The method of claim 12, further comprising etching and pattering the second poly film in the bit line direction after etching and pattering the second poly film in the word line direction.

14. The method of claim 4, wherein the IPD comprises an oxide-nitride-oxide (ONO) layer.

15. A method comprising:
forming a first poly film over a semiconductor layer;
forming a photoresist film over the first poly film;
performing a first exposure on the photoresist film in a first direction;
performing a second exposure on the photoresist in a second direction different than the first direction after performing the first exposure;
forming a floating gate patterned in a lattice form by etching the photoresist film and the first poly film after performing the second exposure;
forming an inter poly dielectric (IPD) over the floating gate;
forming a second poly film over the IPD; and then
patterning a control gate by etching the second poly film.

16. The method of claim 15, wherein the first direction is a word line direction and the second direction is a bit line direction.

17. The method of claim 15, further comprising forming the IPD over both sides of the floating gate in a bit line direction and over both sides of the floating gate in a word line direction.

18. The method of claim 15, wherein the second poly film is formed over both sides of the IPD in a bit line direction and over both sides of the IPD in a word line direction.

19. The method of claim 15, wherein patterning the control gate by etching the second poly film comprises etching and pattering the second poly film in at least one of a bit line direction and a word line direction.

20. The method of claim 15, wherein the IPD comprises an oxide-nitride-oxide (ONO) layer.
